(19) United States
(12) Patent Application Publication
(10) Pub. No.: US 2016/0345465 A1
(43) Pub. Date: Nov. 24, 2016

(54) HEAT RADIATOR AND METHOD FORM FORMING THE SAME

(71) Applicants: Sin-Wei HE, Hsinchu County (TW); Chih-Ren Huang, Kaohsiung Ciity (TW)

(72) Inventors: Sin-Wei HE, Hsinchu County (TW); Chih-Ren Huang, Kaohsiung Ciity (TW)

(73) Assignee: FORCECON TECHNOLOGY CO., LTD., Zhubei City (TW)

(21) Appl. No.: 14/714,956

(22) Filed: May 18, 2015

(51) Int. Cl. H05K 7/20; B23P 15/26

(52) U.S. Cl. CPC H05K 7/20263; B23P 15/26

(57) ABSTRACT

A heat radiator includes a seat including a contact board provided to contact with a heat source. The heat dissipating portion includes a series of fins extending from the bottom of the contact board and a groove is defined between every two adjacent fins. At least two heat dissipating plates are mounted to the heat dissipating portion, wherein the at least two heat dissipating plates are separated from each other. Each heat dissipating plate has multiple insertions formed thereon. Each insertion is inserted into a corresponding one of the grooves between two fins, wherein an air passage is defined between two adjacent heat dissipating plates. A spacing is defined between a free end of each of the insertions and a bottom of the corresponding groove, wherein each spacing communicates with a groove in the seat for forming a longitudinally air passage.

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### BACKGROUND OF THE INVENTION

1. Field of the Invention

The present invention relates to a heat radiator, and more particularly to a heat radiator with an enhanced heat dissipating effect and the method for forming the heat radiator.

2. Description of Related Art Including Information Disclosed Under 37 CFR 1.97 and 37 CFR 1.98

Conventional heat radiators in accordance with the prior art are substantially divided into two types including block type and plate type.

The block type heat radiator usually has a great cross-sectional area such that the block type heat has a good thermal conduction effect by a contact area. However, the block type heat is hard to form thin fins thereon such that the heat dissipating effect of terminal portion thereof is not very good. The plate type heat radiator can be formed as a very thin form such that the plate type heat radiator has a good air circulation because an air passage can be formed on two separated heat dissipating plates. However, the thermal conduction effect of the plate type heat radiator is not very good.

The present invention has arisen to mitigate and/or obviate the disadvantages of the conventional heat radiator.

### BRIEF SUMMARY OF THE INVENTION

The main objective of the present invention is to provide an improved heat radiator that has an enhanced heat dissipating effect.

To achieve the objective, the heat radiator in accordance with the present invention comprises a seat including a contact board and a heat dissipating portion formed on a bottom of the contact board, wherein the contact board has a top provided to contact with a heat source. The heat dissipating portion includes a series of fins extending from the bottom of the contact board and a groove is defined between every two adjacent fins. At least two heat dissipating plates are mounted to the heat dissipating portion, wherein the at least two heat dissipating plates are separated from each other. The heat dissipating plate has a thickness between 0.2 to 0.9 mm. Each heat dissipating plate has multiple insertions formed thereon. Each insertion is inserted into a corresponding one of the grooves between two fins, wherein an air passage is defined between two adjacent heat dissipating plates. A spacing is defined between a free end of each of the insertions and a bottom of the corresponding groove, wherein each spacing communicates with a corresponding one of the groove in the seat for forming a longitudinally air passage.

Further benefits and advantages of the present invention will become apparent after a careful reading of the detailed description with appropriate reference to the accompanying drawings.

### BRIEF DESCRIPTION OF THE SEVERAL VIEWS OF THE DRAWINGS

FIG. 1 is a perspective view of a heat radiator A in accordance with the present invention;

FIG. 2 is an exploded perspective view of the heat radiator in FIG. 1;

FIG. 3 is a bottom perspective view of a seat of the heat radiator in accordance with the present invention;

FIG. 4 is an enlarged perspective view of a heat dissipating plate of the heat radiator in accordance with the present invention;

FIG. 5 is a top plan view of the heat radiator in FIG. 1;

FIG. 6 is a cross-sectional view of the heat radiator along line A-A in FIG. 5;

FIG. 7 is a cross-sectional view of the heat radiator along line B-B in FIG. 5;

FIG. 8 is a cross-sectional view of the heat radiator along line C-C in FIG. 5;

FIG. 9 is a cross-sectional view of the heat radiator along line D-D in FIG. 5;

FIG. 10 is an enlarged cross-sectional view of a vacuum chamber in the seat of the heat radiator in accordance with the present invention;

FIG. 11 is a cross-sectional view of a second embodiment of the seat of the heat radiator in accordance with the present invention;

FIG. 12 is a perspective view of a second embodiment of the heat dissipating plate of the heat radiator in accordance with the present invention;

FIG. 13 is a perspective view of a second embodiment of the heat radiator in accordance with the present invention, wherein the fins respectively radially extend from a bottom of the contact board of the seat;

FIG. 14 is a partially exploded perspective view of the heat radiator in FIG. 13;

FIG. 15 is a perspective view for showing a first connecting type of the seat and the heat dissipating plate in FIG. 13; and

FIG. 16 is a perspective view for showing a second connecting type of the seat and the heat dissipating plate in FIG. 13.

### DETAILED DESCRIPTION OF THE INVENTION

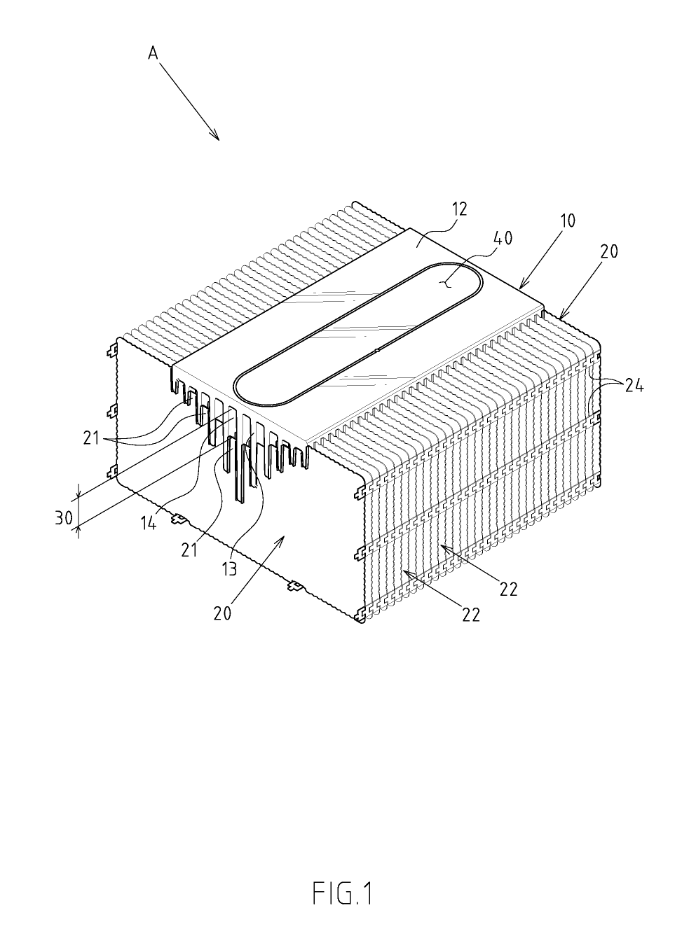

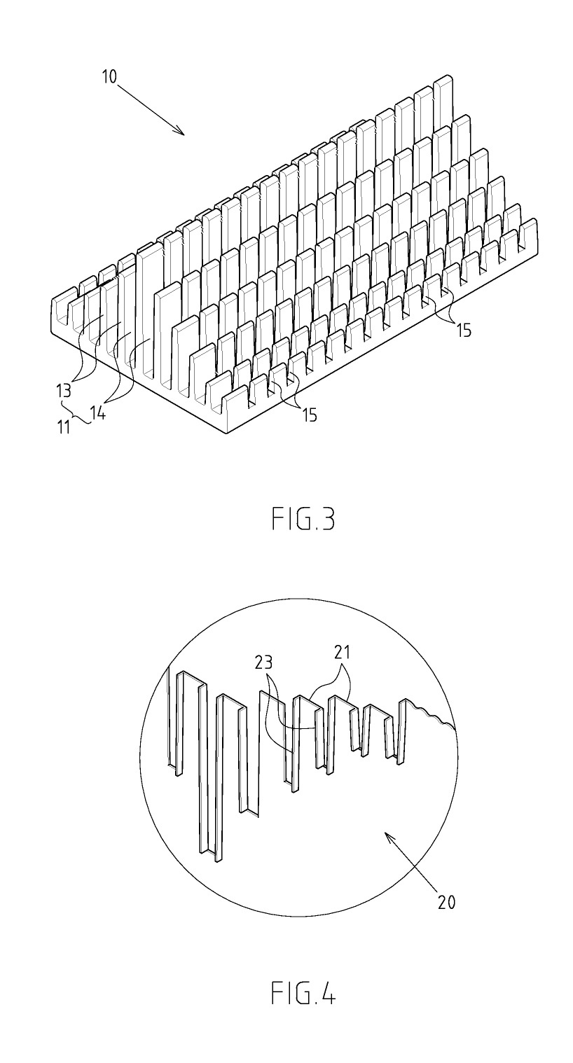

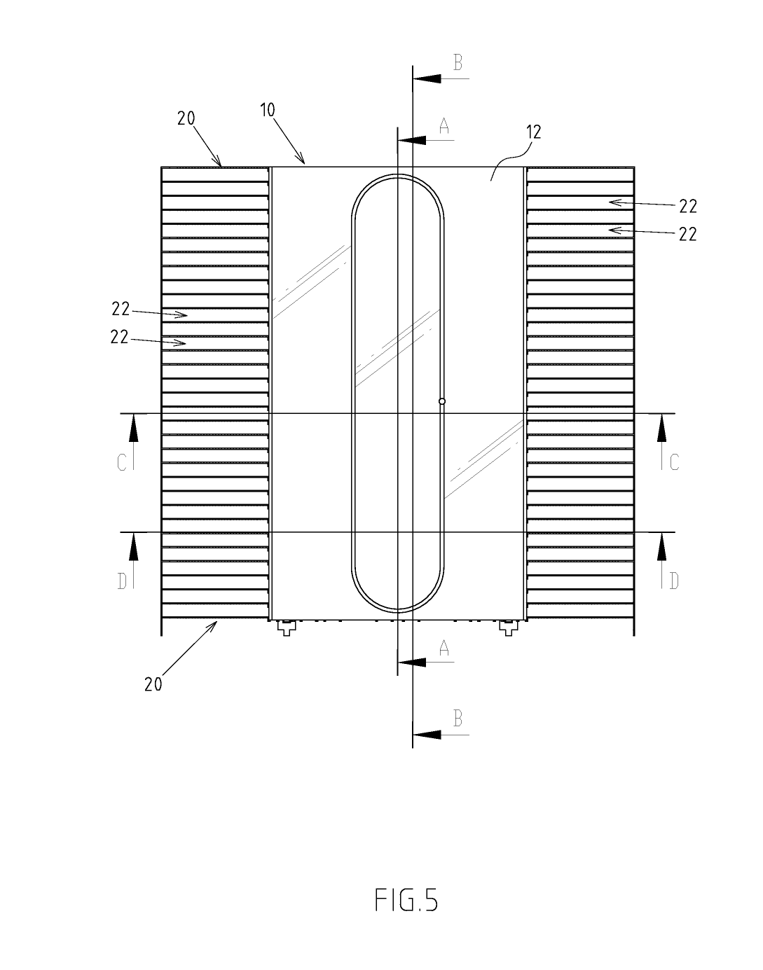

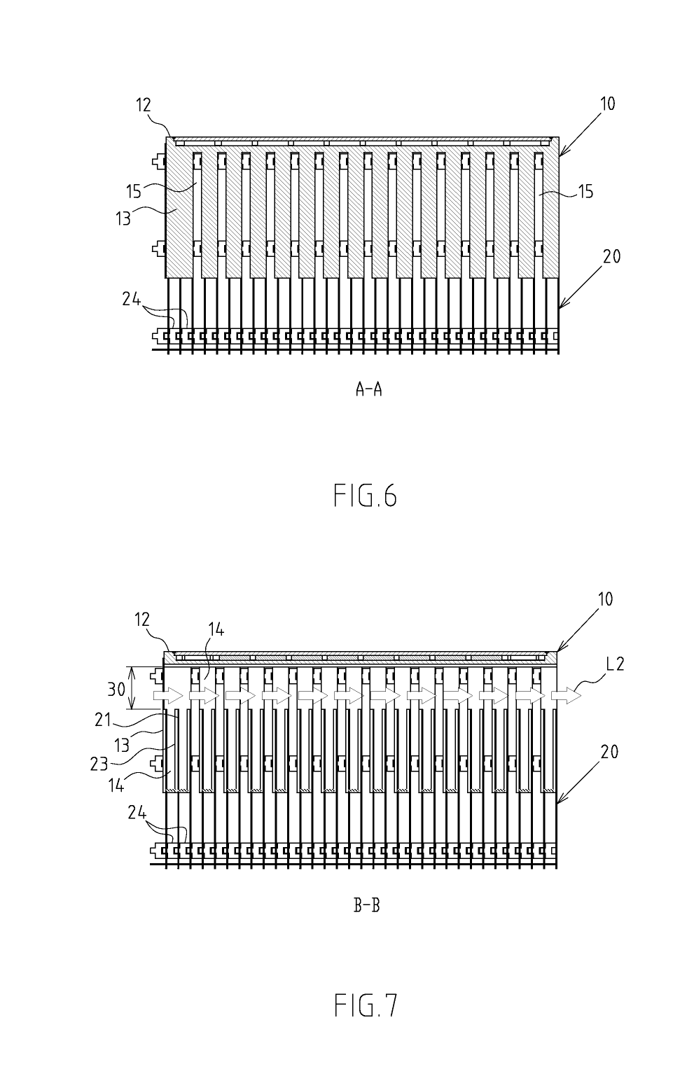

Referring to the drawings and initially to FIGS. 1-9, a heat radiator in accordance with the present invention comprises a seat 10 including a contact board 12 and a heat dissipating portion 11 formed on a bottom of the contact board 12, wherein the contact board 12 has a top provided to contact with a heat source (such as a CPU of a computer or an LED) 05. The heat dissipating portion 11 includes a series of fins 13 extending from the bottom of the contact board 12 and a groove 14 is defined between every two adjacent fins 13. At least two heat dissipating plates 20 are mounted to the heat dissipating portion 11, wherein the at least two heat dissipating plates 20 are separated from each other. In the preferred embodiment of the present invention, the heat dissipating plate 20 is made of copper and has a thickness between 0.2 to 0.9 mm. Each heat dissipating plate 20 has multiple insertions 21 formed thereon. Each insertion 21 is inserted into a corresponding one of the grooves 14 between two fins 13, wherein an air passage 22 is defined between two adjacent heat dissipating plates 20. With reference to FIG. 7, a spacing 30 is defined between a free end of each of the insertions 21 and a bottom of the corresponding groove 14, wherein each spacing 30 communicates with a corresponding one of the groove 14 in the seat 10 for forming a longitudinally air passage (not numbered).

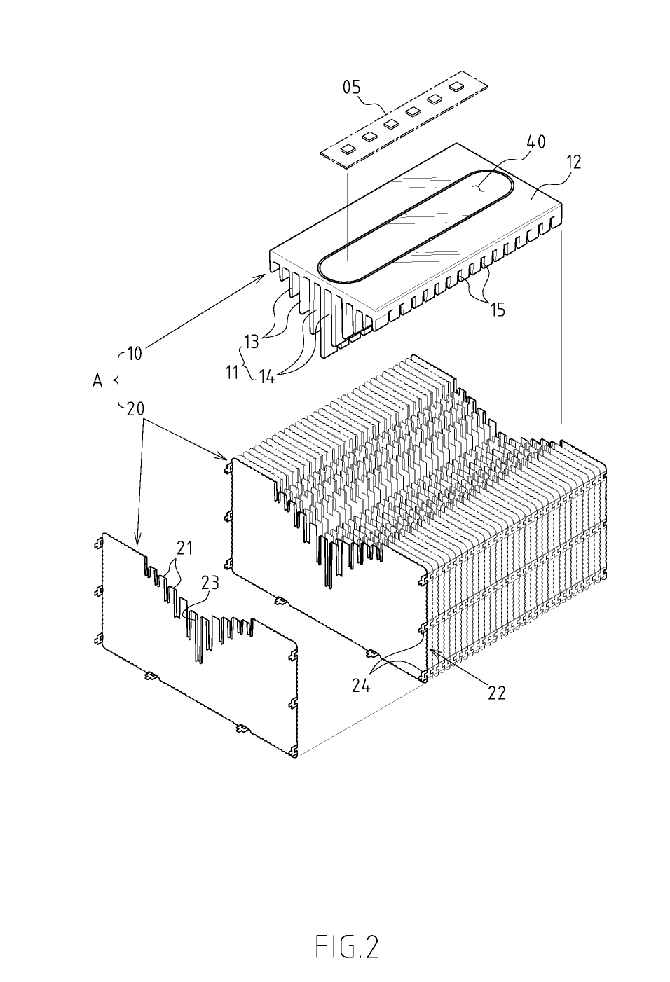

With reference to FIGS. 2, 3, 7 and 8, the seat 10 includes a series of lateral air passages 15 defined therein. The lateral air passage 15 extends through the fins 12 and communicates with the air passage 22 between the heat dissipating plates 20 such that the heat dissipating spacing in the seat 10 is capable of communicating with the air passage 22 between the heat dissipating plates 20.

With reference to FIGS. 2, 4 and 8, each insertion 21 of each of the heat dissipating plates 20 has two opposite sides each having a side plate 23 extending therefrom. The side plate 23 abuts against the inner periphery of a corresponding one of the grooves 14 for promoting the connection between the seat 10 and the heat dissipating plates 20 and promoting the area of thermal conduction.

Furthermore, some/all of the insertion 21 is tapered complementally inserted into the corresponding groove 14 such that the deeper the insertion 21 is inserted into the corresponding groove 14, the fastener connection is provided between the insertion 21 and the seat 10.

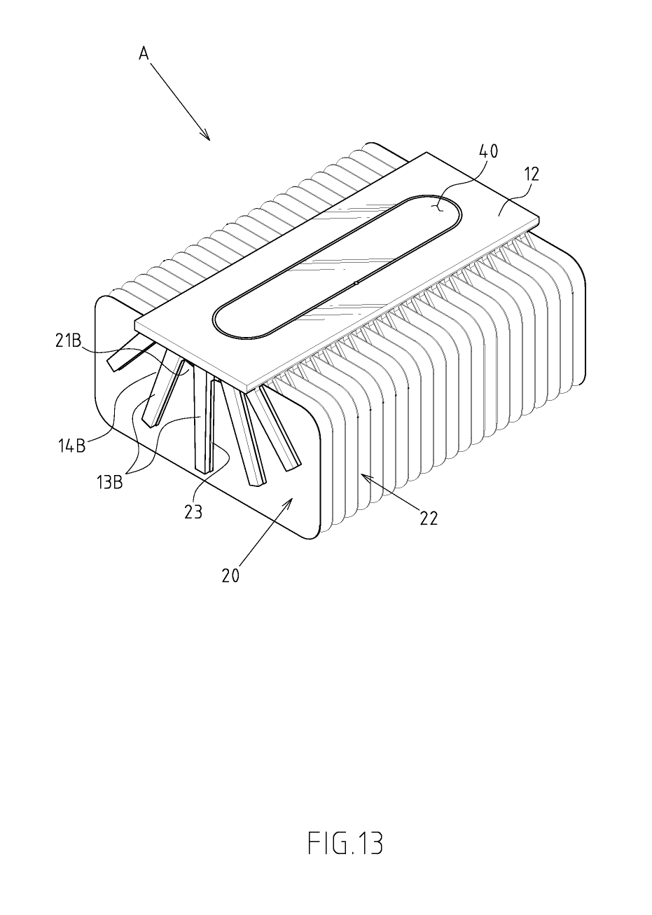

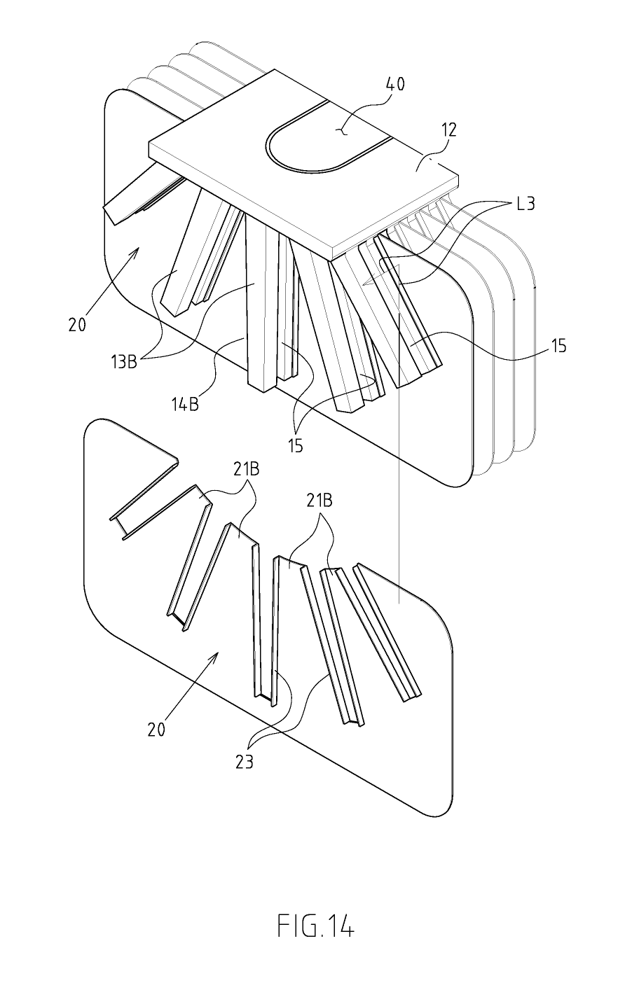

The extending direction of the fins 13 on the seat is vertical or radial relative to the bottom of the contact board 12. With reference to FIGS. 1 to 7, the fins 13 vertically extend from the bottom of the contact board 12. With reference to FIGS. 12 and 13, the fins 13B radially extend from the bottom of the contact board 12.

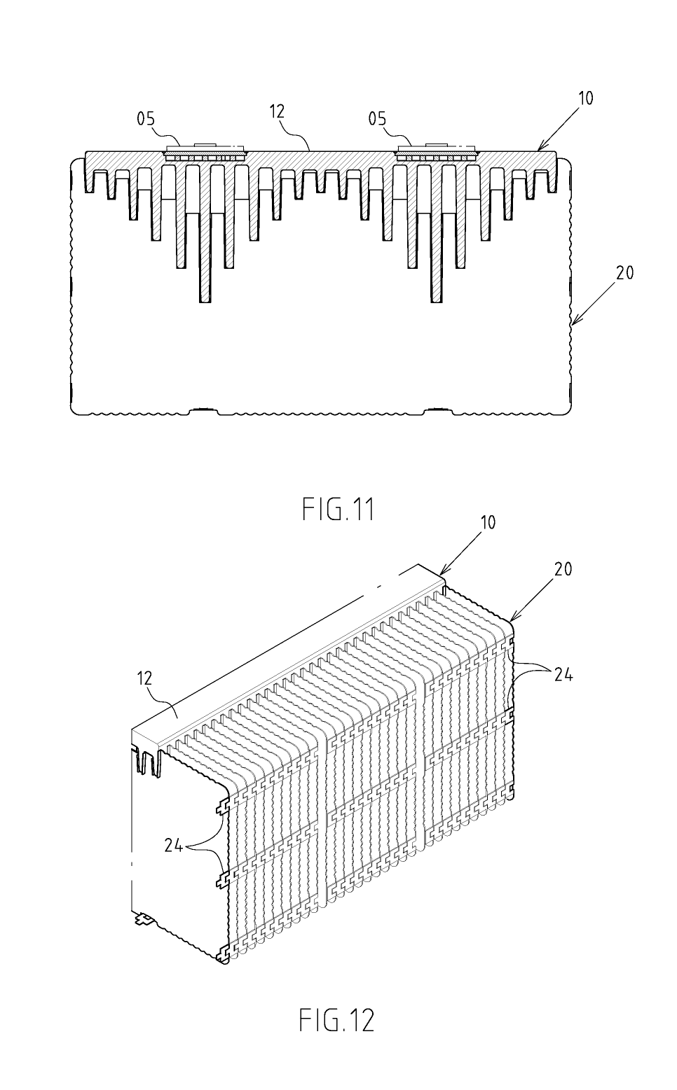

With reference to FIGS. 1 to 3 and 8 to 9, each fin 13 has a height that is gradually reduced relative to a center of the heat source 05 for promoting heat dissipating effect. With reference to FIG. 11, the fins 13 are divided into several groups, wherein each fin 13 of each group has a height that is gradually reduced relative to a center of a corresponding on of the heat sources 05 for promoting heat dissipating effect.

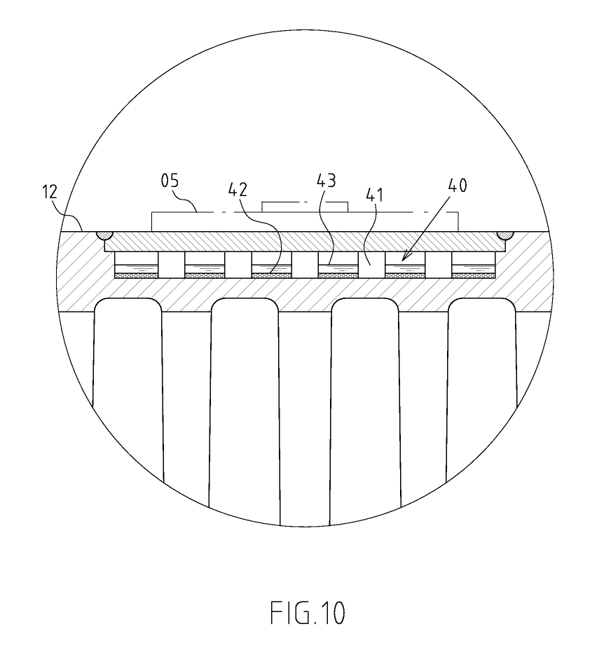

With reference to FIG. 10, a vacuum chamber 40 is defined in the contact board 12 and corresponds to the heat source 05, wherein separators 41 are received in the vacuum chamber 40 and divide the vacuum chamber 40 into multiple rooms (not numbered) and each room contains capillary structure 42 and coolant 43. The seat 10 equally radiates heat due to the vacuum chamber 40 containing the capillary structure 42 and the coolant 43 therein.

With the heat dissipating plate 20 has multiple separating plates 24 vertically extending therefrom and connected to a adjacent heat dissipating plate 20 such that the adjacent heat dissipating plates 20 is separated from each other and has a connection therebetween. With reference to FIG. 12, the heat dissipating plates 20 are divided into several groups when some of the heat dissipating plates 20 has no separating plate extending therefrom.

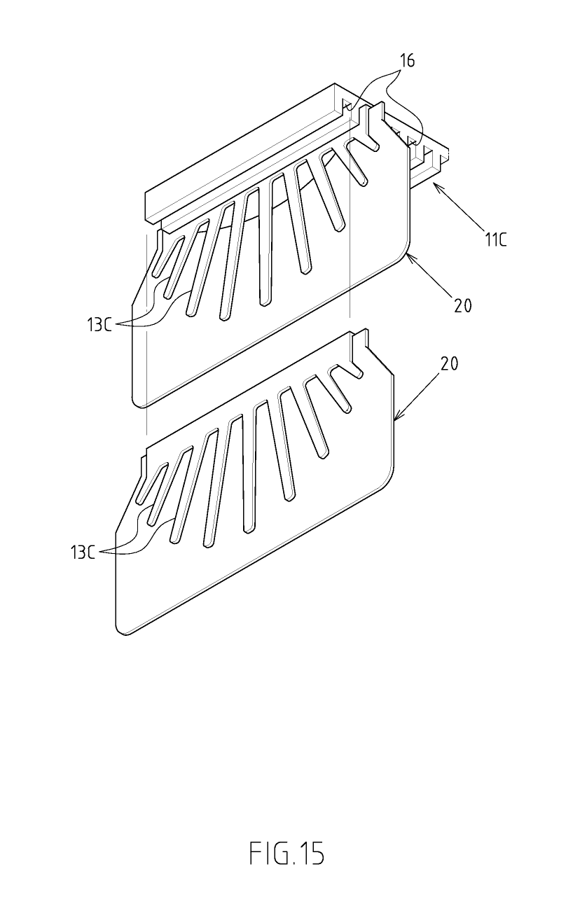

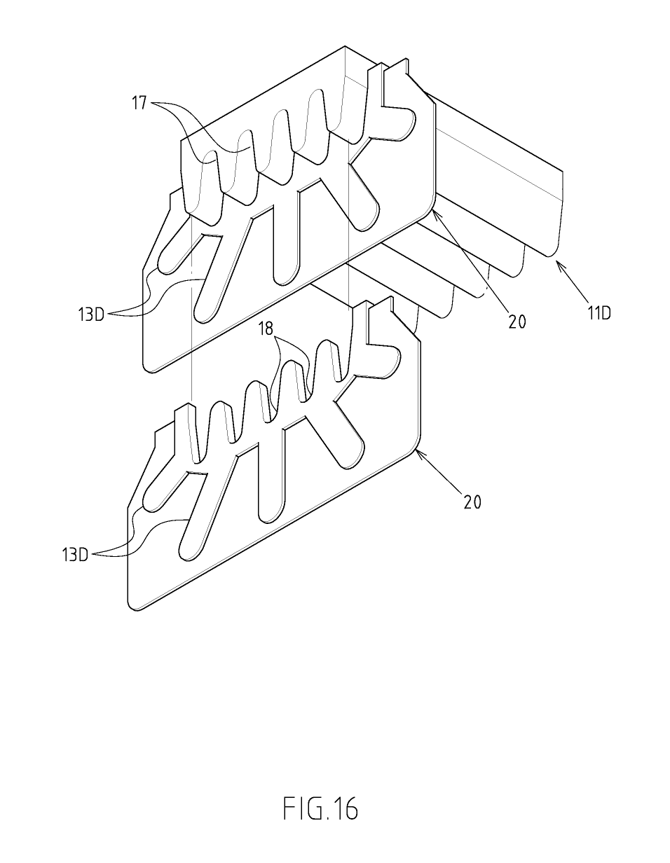

The fins 13 of the seat 10 is integrally formed on the bottom of the contact board 12 or mounted onto the bottom of the contact board 12. In the preferred embodiment of the present invention, as shown in FIGS. 1 to 3, the fins 13 are integrally extending from the bottom of the contact board 12. In the preferred embodiment of the present invention, as shown in FIG. 15, the fins 13C is assembled to the bottom of the contact board 12. The contact board 12 has multiple slots 16 defined in the bottom thereof and the fins 13C are sequentially inserted into a corresponding one of the slots 16. In the preferred embodiment of the present invention, as shown in FIG. 16, the contact board 12 has a first wave-shaped structure 17 formed thereon and each fin 13 has a second wave-shaped structure 18 formed thereon, wherein the first wave-shaped structure 17 and the second wave-shaped structure 18 complementally correspond to each other such that each fin 13 is complementally mounted to the bottom of the contact board 12.

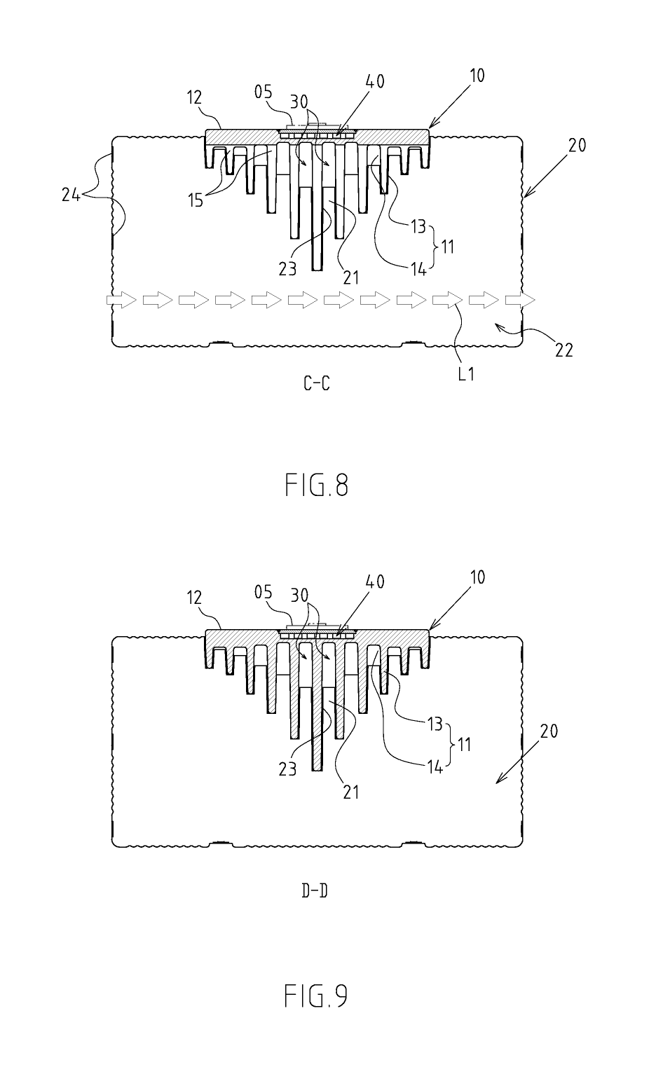

The core technology of the heat radiator A in accordance with the present invention is to combine the seat 10 and the heat dissipating plates 20 that has different structure types. When operating the heat radiator A in accordance with the present invention in a heat dissipating environment (used as a heat dissipating interface of an LED lamp or a CPU in a computer), the heat source 05 (such as an LED lamp or a CPU of a computer) abuts the top of the contact board 12 (as shown in FIGS. 2 and 8). The contact board 12 absorbs the thermal from the heat source 05 and the fins 13 radiate the thermal absorbed by the contact board 12 when the heat source 15 is operated. During heat dissipating, the seat 10 has a solid structure and a groove 14 is defined between every two adjacent fins 13. Furthermore, each groove 14 longitudinally extends through the seat 10 such that the grooves 14 provide an area that is great enough to promote heat dissipating effect of the heat radiator A of the present invention. In addition, the thermal is conducted to the heat dissipating plates 20 via the fins 13. The heat dissipating plate 20 is connected to the insertion 21 that is inserted to the corresponding groove 14 between two adjacent fins 13 such that the fins 13 can effectively transforms the thermal, absorbed by the contact plate 12, to the heat dissipating plate 20. On the other hand, the thickness of the heat dissipating plate 20 is set between 0.2 to 0.9 mm, as a result, each heat dissipating plate 20 can effectively dissipate heat and the extrinsic air current can flow through the air passage 22 (as the arrow L1 shown in FIG. 8) between every two adjacent heat dissipating plates 20 to dissipate the thermal among the heat dissipating plates 20. In addition, the spacing 30 between the top of the insertion 21 and the bottom of the groove 14 communicates with the groove 14 to form the longitudinally air passage such that the extrinsic air current can flow through seat 10 (as the arrow L2 shown in FIG. 7). As described above, the heat radiator A in accordance with the present invention has longitudinally air passages and lateral air passages 15 defined therein for providing air currents that extend in all directions and promoting the heat dissipating effect of the heat radiator in accordance with the present invention.

A method for forming the heat radiator A in accordance with the present invention includes the following steps:
1. Forming a seat 10 by metal extruding process, wherein the seat 10 comprises a contact board 12 and a heat dissipating portion 11 formed on a bottom of the contact board 12. A heat source 05 abuts a top of the contact board 12 (as shown in FIG. 2) when being operated;
2. Forming multiple fins 13 on the bottom of the contact board 12, wherein a groove 14 is defined between every two adjacent fins 13 and longitudinally extends through the seat 10;
3. Forming multiple heat dissipating plates 20 by metal press process and mounted onto the bottom of the contact board 10, wherein the heat dissipating plate 20 has a thickness set between 0.2 to 0.9 mm and multiple insertion 21 extending therefrom;
4. Inserting and positioned the heat dissipating plates 20 to the heat dissipating portion 11, wherein each insertion 21 of each of the heat dissipating plate 20 is inserted into a corresponding one of the grooves 14 such that the heat dissipating plates 20 laterally extend relative to the seat 10 (as shown in FIG. 1);
5. Form an air passage 22 between every two adjacent heat dissipating plate 20, wherein the heat dissipating plates 20 are separated from one another such that an air passage 22 is defined between every two adjacent heat dissipating plates 20 (as shown in FIGS. 1 and 2); and
6. Forming a spacing 30 between a top of each of the insertion 21 of each of the heat dissipating plate 20 and a bottom of the grooves 14 such that a longitudinally air passage is defined in the seat 10 (as shown in FIGS. 1 and 7).

The method as described above, the seat 10 further defines multiple lateral air passages 15 that respectively extend through the fins 13 (as shown in FIGS. 2, 3 and 6). Each lateral air passage 15 communicates with the air passage 22 between every two adjacent heat dissipating plates 20.

The method as described above, the extending direction of the fins 13 of the seat 10 and the insertions 21 of each of the heat dissipating plates 20 is vertical relative to the contact board 12 such that the heat dissipating plate 20 is vertically inserted into the seat 10.

The method as described above, the extending direction of the fins 13B of the seat 10 and the insertions 21B of each of the heat dissipating plates 20 is radial relative to the contact board 12 (as shown in FIGS. 13 and 14) such that the heat dissipating plate 20 is firstly inserted into the lateral air passage 15 and secondly moved into the groove 14 between the two adjacent fins 14B (as the arrow L3 shown in FIG. 14).

Although the invention has been explained in relation to its preferred embodiment, it is to be understood that many other possible modifications and variations can be made without departing from the spirit and scope of the invention as hereinafter claimed.

We claim:

1. A heat radiator comprising:
a seat including a contact board and a heat dissipating portion formed on a bottom of the contact board, wherein the contact board has a top provided to contact with a heat source, and the heat dissipating portion includes a series of fins disposed on the bottom of the contact board and a groove is defined between every two adjacent fins; and
at least two heat dissipating plates mounted to the heat dissipating portion, wherein the at least two heat dissipating plates are separated from each other and each has a thickness between 0.2 to 0.9 mm, each heat dissipating plate having multiple insertions formed thereon and each insertion inserted into a corresponding one of the grooves between two fins, wherein an air passage is defined between two adjacent heat dissipating plates, a spacing defined between a free end of each of the insertions and a bottom of the corresponding groove, wherein each spacing communicates with a corresponding one of the groove in the seat for forming a longitudinally air passage.

2. The heat radiator as claimed in claim 1, wherein the seat includes a series of lateral air passages defined therein, the lateral air passage extending through the fins and communicates with the air passage between the heat dissipating plates such that the heat dissipating spacing in the seat is capable of communicating with the air passage between the heat dissipating plates.

3. The heat radiator as claimed in claim 2, wherein each insertion of each of the heat dissipating plates has two opposite sides each having a side plate extending therefrom, the side plate abutting against the inner periphery of a corresponding one of the grooves for promoting the connection between the seat and the heat dissipating plates and promoting the area of thermal conduction.

4. The heat radiator as claimed in claim 3, wherein the insertion is tapered complementally inserted into the corresponding groove.

5. The heat radiator as claimed in claim 4, wherein the extending direction of the fins on the seat is vertical relative to the bottom of the contact board.

6. The heat radiator as claimed in claim 4, wherein the extending direction of the fins on the seat is radial relative to the bottom of the contact board.

7. The heat radiator as claimed in claim 5, wherein each fin has a height that is gradually reduced relative to a center of the heat source for promoting heat dissipating effect.

8. The heat radiator as claimed in claim 6, wherein each fin has a height that is gradually reduced relative to a center of the heat source for promoting heat dissipating effect.

9. The heat radiator as claimed in claim 7, wherein the fins of the seat is integrally formed on the bottom of the contact board.

10. The heat radiator as claimed in claim 8, wherein the fins of the seat is integrally formed on the bottom of the contact board.

11. The heat radiator as claimed in claim 7, wherein the fins of the seat is mounted onto the bottom of the contact board.

12. The heat radiator as claimed in claim 8, wherein the fins of the seat is mounted onto the bottom of the contact board.

13. A method for forming a heat radiator comprising the steps of:
forming a seat by metal extruding process, wherein the seat comprises a contact board and a heat dissipating portion formed on a bottom of the contact board, a heat source abuts a top of the contact board when being operated;
forming multiple fins on the bottom of the contact board, wherein a groove is defined between every two adjacent fins and longitudinally extends through the seat;
forming multiple heat dissipating plates by metal press process and mounted onto the bottom of the contact board, wherein the heat dissipating plate has a thickness set between 0.2 to 0.9 mm and multiple insertion extending therefrom;
inserting and positioned the heat dissipating plates to the heat dissipating portion, wherein each insertion of each of the heat dissipating plate is inserted into a corresponding one of the grooves such that the heat dissipating plates laterally extend relative to the seat;
form an air passage between every two adjacent heat dissipating plate, wherein the heat dissipating plates are separated from one another such that an air passage is defined between every two adjacent heat dissipating plates; and
forming a spacing between a top of each of the insertion of each of the heat dissipating plate and a bottom of the grooves such that a longitudinally air passage is defined in the seat.

14. The method as claimed in claim 13, wherein the seat further defines multiple lateral air passages that respectively extend through the fins, each lateral air passage communicating with the air passage between every two adjacent heat dissipating plates.

15. The method as claimed in claim 14, wherein the extending direction of the fins of the seat and the insertions of each of the heat dissipating plates is vertical relative to the contact board such that the heat dissipating plate is vertically inserted into the seat.

16. The method as claimed in claim 14, wherein the extending direction of the fins of the seat and the insertions of each of the heat dissipating plates is radial relative to the contact board such that the heat dissipating plate is firstly inserted into the lateral air passage and secondly moved into the groove between the two adjacent fins.
